(19) United States
(12) Patent Application Publication
(10) Pub. No.: US 2026/0353605 A1
(43) Pub. Date: Nov. 5, 2026

(54) COOLANT DISTRIBUTION UNIT

(71) Applicant: COOLER MASTER CO., LTD., Taipei City (TW)

(72) Inventors: Feng-Mu LIAO, Taipei City (TW); Shui-Fa TSAI, Taipei City (TW)

(73) Assignee: COOLER MASTER CO., LTD., Taipei City (TW)

(21) Appl. No.: 19/662,276

(22) Filed: Apr. 29, 2026

(30) Foreign Application Priority Data
Apr. 30, 2025 (TW) 114204323

(51) Int. Cl. H05K 7/20

(52) U.S. Cl. CPC H05K 7/20272; H05K 7/20263; H05K 7/20981

(57) ABSTRACT

Coolant distribution unit, comprising a manifold assembly, a cooling liquid radiator and a pump. The manifold assembly is configured to split flow, or converge flows, of a working fluid. The cooling liquid radiator is in fluid communication with the manifold assembly and configured to allow the working fluid to circulate, cooling liquid radiator and manifold assembly together forming a columnar structure and surrounding a gas flow channel. The pump is in fluid communication with cooling liquid radiator and manifold assembly; the pump being configured to pump the working fluid in the cooling liquid radiator to the manifold assembly.

This application claim priority from Taiwan Patent App. No. 114204323, filed Apr. 30, 2025, the content of which (including all attachments filed therewith) is hereby incorporated by reference in its entirety.

### TECHNICAL FIELD

The present disclosure relates to a coolant distribution unit, and in particular to a coolant distribution unit that integrates a manifold and a columnar cooling liquid radiator.

### BACKGROUND OF THE DISCLOSURE

Conventional coolant distribution units (CDUs) have various technical problems in their design. Firstly, their cooling liquid radiator is generally rectangular and only installed on one side of the CDU; consequently, the overall heat exchange area is limited, so heat exchange efficiency is affected. Secondly, in a conventional CDU, the cooling liquid radiator and the manifold are independent elements, and need to be connected via an additional pipe; this not only increases material costs but also makes the assembly process more complex, while also increasing the risk of water leakage. Furthermore, in terms of configuration, most fans in existing CDUs are arranged in an array at the front or back of the radiator, and since the number of fans is larger, the control system is relatively complex. In addition, the distance between the fan and the radiator is very short, so the rotary flow field generated by the fan acts directly on the surface of the cooling liquid radiator, forming a non-uniform flow field and thus lowering the cooling efficiency.

To summarize, in view of at least the above noted drawbacks, there is still room for improvement and optimization of the structure of existing CDUs with regard to cooling efficiency, system integration and stability.

### SUMMARY OF THE DISCLOSURE

Exemplary embodiments of the present disclosure provide a coolant distribution unit, that may, but is not requires to, address the drawback of conventional CDUs, such as for example and without limitation, insufficient heat dissipation area, and increased risk of water leakage and pipe connection costs due to separation of elements.

A coolant distribution unit according to an example embodiment of the present disclosure can comprise a manifold assembly, a cooling liquid radiator and a pump. The manifold assembly can be configured to split flow, or converge flows, of a working fluid. The cooling liquid radiator can be in fluid communication with the manifold assembly and configured to allow the working fluid to circulate, the cooling liquid radiator and the manifold assembly together forming, for example, a columnar structure and surrounding a gas flow channel. The pump can be in fluid communication with the cooling liquid radiator and the manifold assembly, the pump being configured, for example, to pump the working fluid in the cooling liquid radiator to the manifold assembly.

In the coolant distribution unit according to an example embodiment of the present disclosure can, the cooling liquid radiator and the manifold assembly can be integrated as a columnar structure, such that the cooling liquid radiator can be, for example, distributed over the entire peripheral surface of the coolant distribution unit; in this way, the cooling area can be increased to increase the space utilization rate. In an exemplary implementation, this can, for example and without limitation, help to reduce the cost of pipe material used to connect the cooling liquid radiator and the manifold assembly in series, and also, for example and without limitation, the piping production process. In an exemplary implementation, this can, for example and without limitation, further increase the space utilization rate and reduce the probability of water leakage.

The above description of the summary of the present disclosure and the following description of the example embodiments are intended to illustrate and explain the principles of the present disclosure and can facilitate a further understanding of the appended claims of the present disclosure.

### BRIEF DESCRIPTION OF THE DRAWINGS

A more complete appreciation of the present disclosure and many of the attendant advantages thereof will be readily obtained as the same becomes better understood by reference to the following detailed description when considered in connection with the accompanying drawings, wherein:

FIG. 1 is an illustrative three-dimensional schematic drawing of a coolant distribution unit according to a first example embodiment of the present disclosure.

FIG. 2 is an exploded schematic drawing of the coolant distribution unit in FIG. 1.

FIG. 3 is a schematic drawing of the flow direction of working fluid in the coolant distribution unit in FIG. 1.

FIG. 4 is a schematic drawing of the flow direction of working fluid in the coolant distribution unit in FIG. 1, viewed from a different angle.

FIG. 5 is an illustrative three-dimensional schematic drawing of a coolant distribution unit according to a second embodiment of the present disclosure.

FIG. 6 is an illustrative three-dimensional schematic drawing of a coolant distribution unit according to a third embodiment of the present disclosure.

FIG. 7 is a three-dimensional schematic drawing of the coolant distribution unit in FIG. 6 with the casing omitted.

FIG. 8 is an exploded schematic drawing of the coolant distribution unit in FIG. 6 with the casing omitted.

FIG. 9 is a schematic drawing of the flow direction of working fluid in the coolant distribution unit in FIG. 6.

FIG. 10 is an illustrative three-dimensional schematic drawing of a coolant distribution unit according to a fourth embodiment of the present disclosure.

FIG. 11 is an illustrative three-dimensional schematic drawing of a coolant distribution unit according to a fifth embodiment of the present disclosure with the casing omitted.

FIG. 12 is another three-dimensional schematic drawing of the coolant distribution unit in FIG. 11.

FIG. 13 is a three-dimensional schematic drawing of the coolant distribution unit in FIG. 11 with the external cooling fans omitted.

FIG. 14 is a schematic drawing of the flow direction of working fluid in the coolant distribution unit in FIG. 13.

### DETAILED DESCRIPTION OF EXEMPLARY EMBODIMENTS

Detailed features and advantages of embodiments of the present disclosure are described in detail below in example embodiments, the content of which is sufficient to allow any person skilled in the art to understand and thereby implement the technical content of embodiments of the present disclosure, and any person skilled in the art can easily understand the relevant objectives and advantages of the present disclosure on the basis of the content disclosed herein, the claims and the drawings. The embodiments below describe the viewpoints of the present disclosure in further detail, but none of these viewpoints limits the scope of the present disclosure. Accordingly, those of ordinary skill in the art will recognize that various changes and modifications of the embodiments described herein can be made without departing from the scope and spirit of the described disclosure. Also, descriptions of well-known functions and constructions are omitted for clarity and conciseness

An example embodiment of the present disclosure provides a coolant distribution unit (CDU), suitable for, for example and without limitation, data centers, liquid-cooled servers or other high-performance thermal management applications. Furthermore, the coolant distribution unit of the present disclosure can have the characteristics of modularization and structural integration, such that dimensions can be adjusted and configurations optimized according to different application requirements. According to exemplary implementations, in small-scale configurations, the unit can be applied to the liquid-cooling heat dissipation requirements of desktop personal computers (PCs), workstations, high power-density electronic elements, new energy vehicles and other devices. According to exemplary implementations, in large-scale configurations, the unit can be especially suitable for the water-cooling heat dissipation systems of server cabinets and other data center equipment, providing a stable and highly efficient thermal management solution.

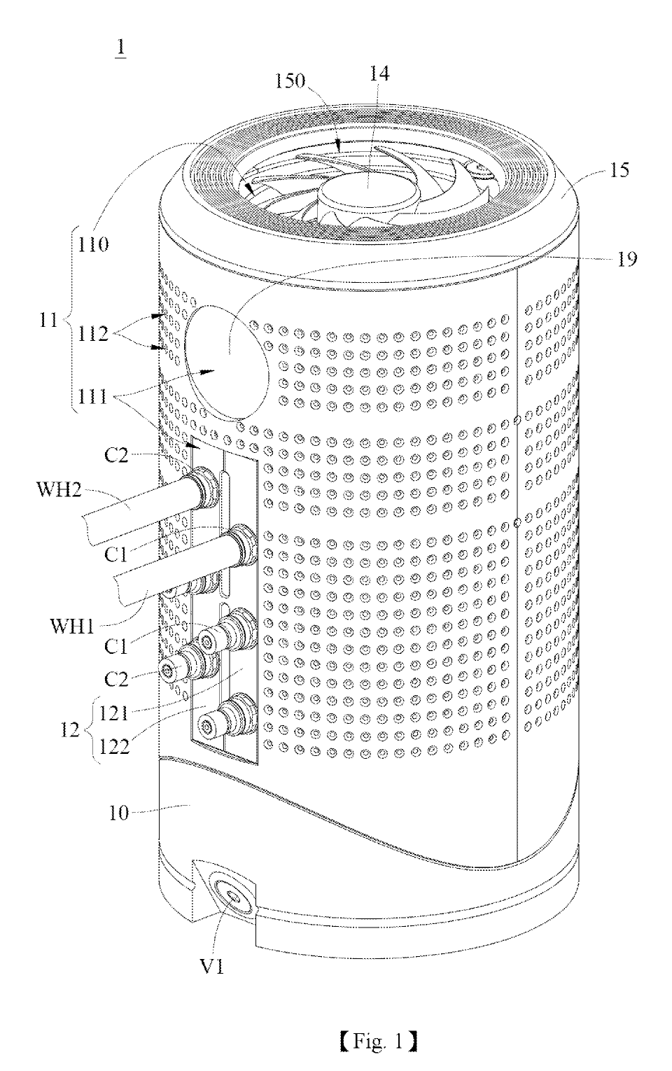

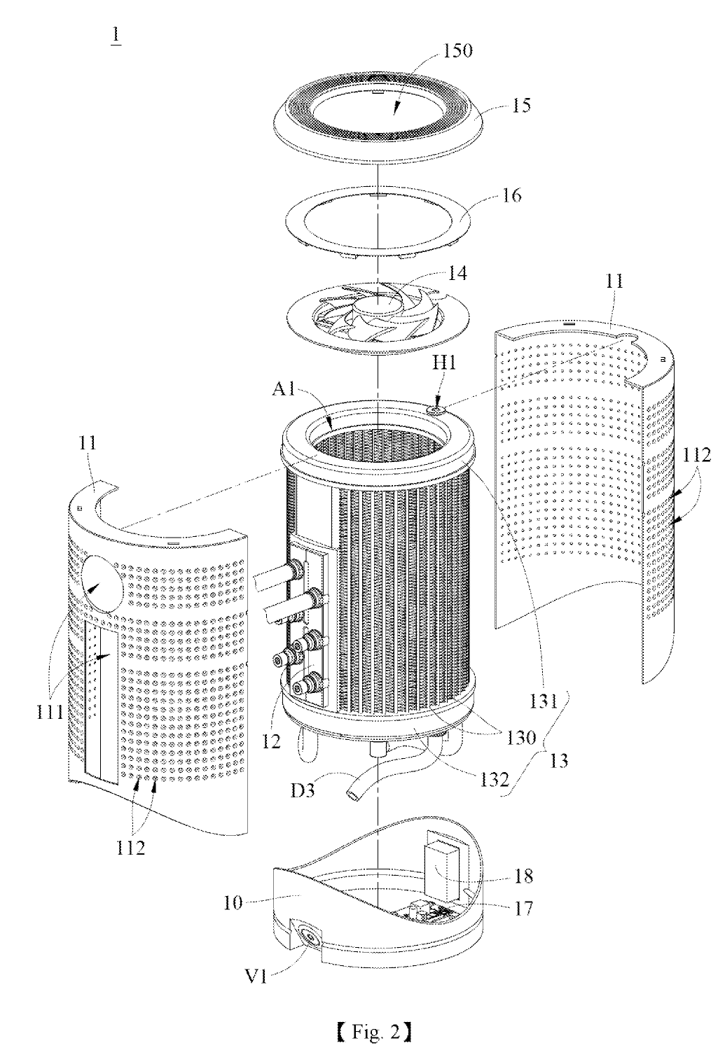

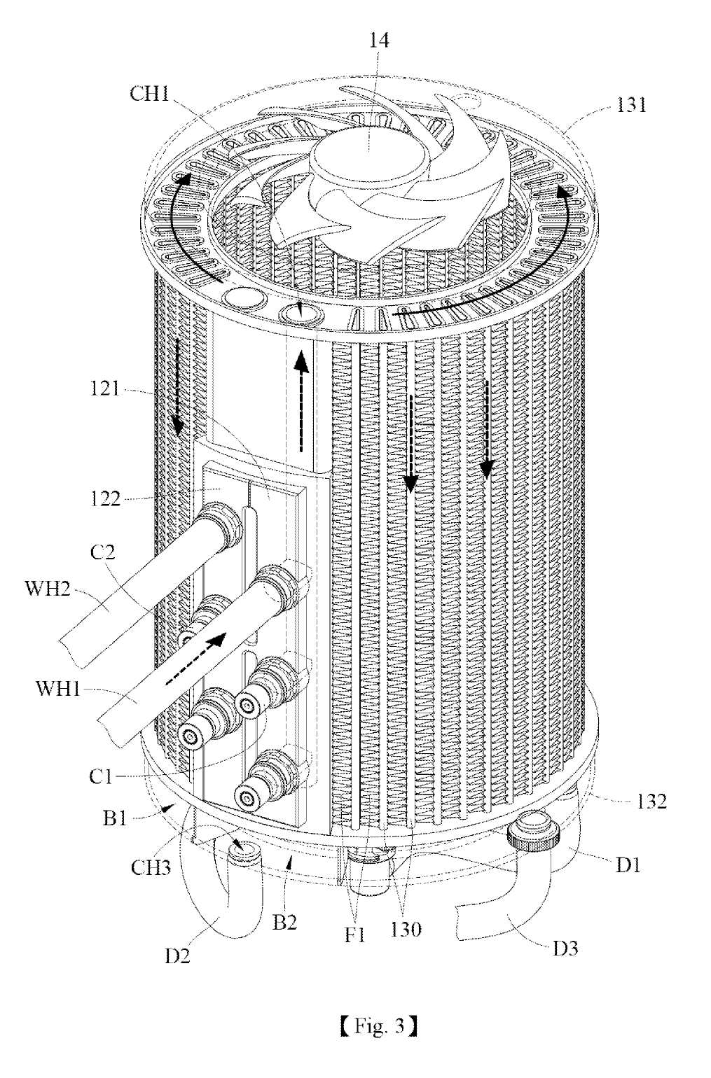

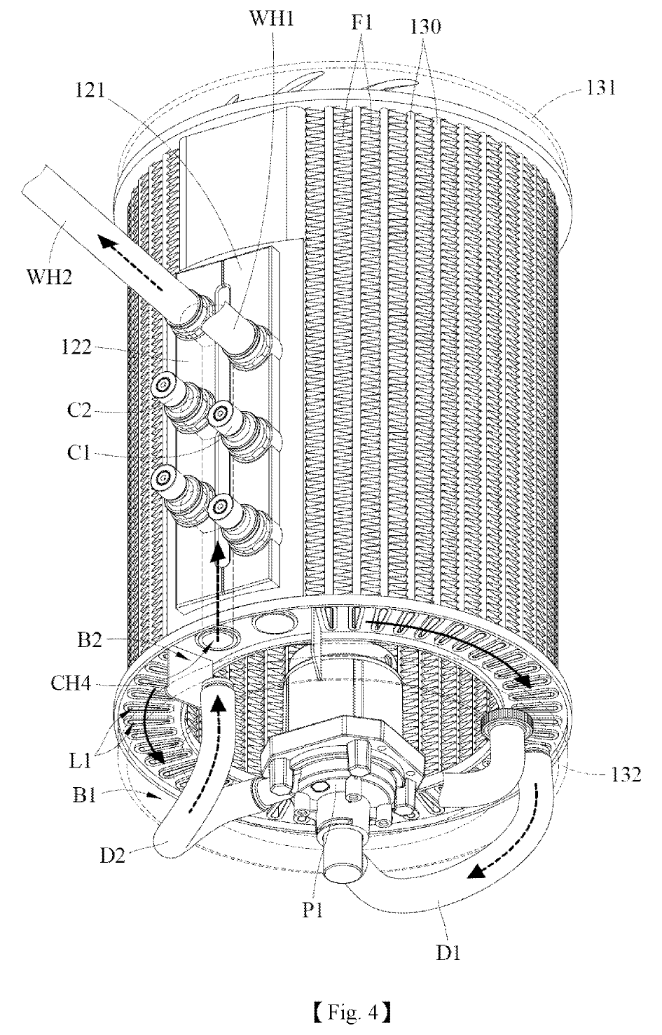

Referring to FIGS. 1-4, FIG. 1 is an illustrative three-dimensional schematic drawing of a coolant distribution unit according to a first example embodiment of the present disclosure, FIG. 2 is an exploded schematic drawing of the coolant distribution unit in FIG. 1, FIG. 3 is a schematic drawing of the flow direction of working fluid in the coolant distribution unit in FIGS. 1 and 4 is a schematic drawing of the flow direction of working fluid in the coolant distribution unit in FIG. 1, viewed from a different angle.

The coolant distribution unit 1 in this example embodiment may comprise a base 10, a casing 11, a manifold assembly 12, a cooling liquid radiator 13, a pump P1, an on-axis cooling fan 14, a water replenishment hole H1, a water drain valve V1, an air guiding cover 15, a light strip 16, a control circuit board 17, a power supply connector switch module 18 and a display screen module 19.

In an exemplary implementation, the casing 11 can be fixed to the base 10, and the casing 11 and the base 10 together form an accommodating trough. The casing 11 can have a ventilation port structure 110, an opening structure 111 and an openwork structure 112.

In an exemplary implementation, the manifold assembly 12 can be configured to split flow, or converge flows, of a working fluid. The manifold assembly 12 can comprise a flow-converging manifold 121 and a flow-splitting manifold 122, wherein the flow-converging manifold 121 has multiple quick-release inflow connectors C1 and can be configured to converge the flows of working fluid, and the flow-splitting manifold 122 can have multiple quick-release outflow connectors C2 and can be configured to split the flow of working fluid. In this example embodiment, the flow-converging manifold 121 and the flow-splitting manifold 122 can be fixedly connected to each other, but the present disclosure is not limited to this.

In an exemplary implementation, the cooling liquid radiator 13 can be in fluid communication with the manifold assembly 12, and the cooling liquid radiator 13 can be configured to allow working fluid to circulate. The cooling liquid radiator 13 and the manifold assembly 12 together can form a columnar structure and can be arranged in the accommodating trough, and the columnar structure can surround a gas flow channel A1. In this example embodiment, the columnar structure can be, for example, cylindrical.

In an exemplary implementation, the ventilation port structure 110 of the casing 11 can correspond to and expose the gas flow channel A1, to facilitate the entry and exit of gas flow. The opening structure 111 of the casing 11 can correspond to and expose the manifold assembly 12. The openwork structure 112 of the casing 11 can surround the cooling liquid radiator 13 and form channels allowing air to circulate between inner and outer spaces, such that, for example, air can circulate between the gas flow channel A1 and the outer space via the openwork structure 112.

In an exemplary implementation, the pump P1 can be arranged in the accommodating trough and in fluid communication with the cooling liquid radiator 13 and the manifold assembly 12, and the pump P1 can be configured to pump working fluid in the cooling liquid radiator 13 to the manifold assembly 12. In this example embodiment, the manifold assembly 12 and the cooling liquid radiator 13 can be integrated and welded together, but the present disclosure is not limited to this. In other embodiments, the manifold assembly and the cooling liquid radiator may for example be fixed to each other by locking fixing members such as screws, and may for example be in fluid communication with each other via pipe members.

In yet further example implementation, the cooling liquid radiator 13 may comprise multiple metal heat exchange tubes 130, a liquid exit water collection pipe 131, a liquid entry water collection pipe 132 and multiple cooling fins F1. The metal heat exchange tubes 130 can be arranged around the gas flow channel A1. The liquid exit water collection pipe 131 and the liquid entry water collection pipe 132 can be respectively located at two opposite ends of the metal heat exchange tubes 130, and the liquid exit water collection pipe 131 and the liquid entry water collection pipe 132 can be in fluid communication with the metal heat exchange tubes 130. The metal heat exchange tubes 130 may for example be flat tubes, but the present disclosure is not limited to this.

In an exemplary implementation, the manifold assembly 12 may be fixed to the liquid exit water collection pipe 131 and the liquid entry water collection pipe 132 and located between the liquid exit water collection pipe 131 and the liquid entry water collection pipe 132, and the manifold assembly 12 can be arranged between two of the metal heat exchange tubes 130. In yet further example implementation, the flow-converging manifold 121 of the manifold assembly 12 may be welded to the liquid exit water collection pipe 131 and in fluid communication with the liquid exit water collection pipe 131 via a first connecting hole CH1, and the liquid exit water collection pipe 131 can be configured to split the flow of working fluid from the flow-converging manifold 121 into the metal heat exchange tubes 130. The liquid entry water collection pipe 132 can be in fluid communication with the pump P1 and configured to converge the flows of working fluid from the metal heat exchange tubes 130 and guide same to the pump P1, and the pump P1 can be configured to pump working fluid from the liquid entry water collection pipe 132 to the flow-splitting manifold 122 of the manifold assembly 12. In still further example implementation, the liquid entry water collection pipe 132 can have a liquid entry water collection chamber B1 and a linking chamber B2 which can be separated from each other. The liquid entry water collection chamber B1 can be in fluid communication with the metal heat exchange tubes 130 via multiple collecting holes L1, and the liquid entry water collection chamber B1 can be in fluid communication with the pump P1 via a second connecting hole (not labeled) and a first pipe D1. The linking chamber B2 can be in fluid communication with the pump P1 via a third connecting hole CH3 and a second pipe D2, and in fluid communication with the flow-splitting manifold 122 of the manifold assembly 12 via a fourth connecting hole CH4. The flow-splitting manifold 122 of the manifold assembly 12 may be welded to the liquid entry water collection pipe 132. Through the above configuration, the pump P1 can be configured to pump working fluid from the liquid entry water collection chamber B1 to the flow-splitting manifold 122 of the manifold assembly 12 via the linking chamber B2. The first pipe D1 and the second pipe D2 may for example be hoses, but the present disclosure is not limited to this.

In an exemplary implementation, the cooling fins F1 may be connected and arranged between two adjacent metal heat exchange tubes 130, to increase the cooling area of the cooling liquid radiator 13.

In an exemplary implementation, the on-axis cooling fan 14 can be arranged in the gas flow channel A1, and the on-axis cooling fan 14 can be configured to generate a cooling gas flow to cool the cooling liquid radiator 13.

In an exemplary implementation, the water replenishment hole H1 can be located on the liquid exit water collection pipe 131, to facilitate the replenishment of working fluid. The water drain valve V1 can be connected to the liquid entry water collection pipe 132 via a third pipe D3, and configured to selectively discharge working fluid. According to an example implementation, this can further increase convenience of maintenance and safety in use. However, the present disclosure is not limited to the positions of arrangement of the water replenishment hole H1 and the water drain valve V1 mentioned above. It should be understood that, in example implementations, the water replenishment hole and the water drain valve may be arranged at different element positions in the fluid circuit according to actual design requirements. The third pipe D3 may for example be a hose, but the present disclosure is not limited to this.

In an exemplary implementation, the air guiding cover 15 can be fitted to the casing 11, and the air guiding cover 15 can be located at the end of the columnar structure that is opposite the base 10. The air guiding cover 15 can have an air guiding hole 150, and the air guiding hole 150 can expose the gas flow channel A1, and can be configured to guide the cooling gas flow generated by the on-axis cooling fan 14 to flow between the gas flow channel A1 and the outer space.

In an exemplary implementation, the light strip 16 can be arranged on the air guiding cover 15 and surround the air guiding hole 150, such that a dazzling effect can be generated by changes in the light of the light strip 16 being projected onto the on-axis cooling fan 14. The light strip 16 may for example be an LED light strip, but the present disclosure is not limited to this.

In example implementations of example embodiment, both the air guiding cover and the light strip may be optional, and the present disclosure is not limited to this. As an example, in other embodiments, the coolant distribution unit may not have the air guiding cover and/or the light strip.

In an exemplary implementation, the power supply connector switch module 18 and the display screen module 19 can be electrically connected to the control circuit board 17. The control circuit board 17 and the power supply connector switch module 18 can be arranged on the base 10, and the display screen module 19 can be arranged on the casing 11. The opening structure 111 of the casing 11 can expose at least part of the display screen module 19, such that the display screen module 19 can be at least partially exposed through the opening structure 111 of the casing 11, for example to provide the user with a monitoring and operating interface. In a further example implementation, the power supply connector switch module 18 can be an interface providing the coolant distribution unit 1 with power input and switch control.

As shown in FIGS. 3 and 4, according to exemplary implementation, external working fluid to be cooled can be inputted through a hot liquid pipe member WH1 via the quick-release inflow connector C1 on the flow-converging manifold 121, and enter the liquid exit water collection pipe 131 through the first connecting hole CH1. The liquid exit water collection pipe 131 can be configure to then split the flow of the working fluid to be cooled and guide same into the metal heat exchange tubes 130. According to an example implementation, when the working fluid to be cooled is flowing through the metal heat exchange tubes 130, the cooling surface area can be increased by the cooling fins F1, and at the same time the gas flow generated by the on-axis cooling fan 14 can flow through the gas flow channel A1, carrying away the heat of the cooling fins F1, the metal heat exchange tubes 130 and the working fluid therein, to achieve a cooling effect. The cooled working fluid converges in the liquid entry water collection chamber B1 of the liquid entry water collection pipe 132 through the collecting holes L1 from the other ends of the metal heat exchange tubes 130, and is then delivered to the pump P1 through the second connecting hole and the first pipe D1. The pump P1 then pumps the cooled working fluid to the linking chamber B2 of the liquid entry water collection pipe 132 via the second pipe D2 and the third connecting hole CH3, and further guides same into the flow-splitting manifold 122 via the fourth connecting hole CH4, and finally outputs same to external equipment (such as a cold plate) (not shown) through a cold liquid pipe member WH2 via the quick-release outflow connector C2 on the flow-splitting manifold 122.

Through the above configuration according to example implementation, the cooling liquid radiator 13 and the manifold assembly 12 can be integrated as a columnar structure, such that the cooling liquid radiator 13 can be distributed over the entire peripheral surface of the coolant distribution unit 1; in such a way, according to example implementation, the cooling area can be increased to increase the space utilization rate. According to yet further example implementation, the cooling liquid radiator 13 and the manifold assembly 12 can be welded together; this, for example and without limitation, can help to reduce the cost of pipe material used to connect the cooling liquid radiator 13 and the manifold assembly 12 in series, and also the piping production process, and can, for example and without limitation, further increase the space utilization rate and reduce the probability of water leakage. According to still further example implementation, having the on-axis cooling fan 14 arranged in the gas flow channel A1, such that the on-axis cooling fan 14 is located on a central axis of the gas flow channel A1, can facilitate more uniform circulation and distribution of the gas flow field over the cooling liquid radiator 13.

In the first example embodiment, the on-axis cooling fan 14 can be an axial-flow fan, configured to generate an axial cooling gas flow, discharging air in the gas flow channel A1 through the air guiding hole 150 of the air guiding cover 15, and by the principle of negative pressure, guiding external air to enter through the openwork structure 112 of the casing 11, and flow into the gas flow channel A1 through the gaps between the metal heat exchange tubes 130 and the cooling fins F1 of the cooling liquid radiator 13, thereby for example and without limitation enhancing the overall heat exchange effect. When the gas flow passes through the gaps between the metal heat exchange tubes 130 and the cooling fins F1, it can at the same time carry away the heat distributed over the metal heat exchange tubes 130 and the cooling fins F1, thereby for example and without limitation increasing the cooling efficiency. However, the present disclosure is not limited to the type of the on-axis cooling fan mentioned above.

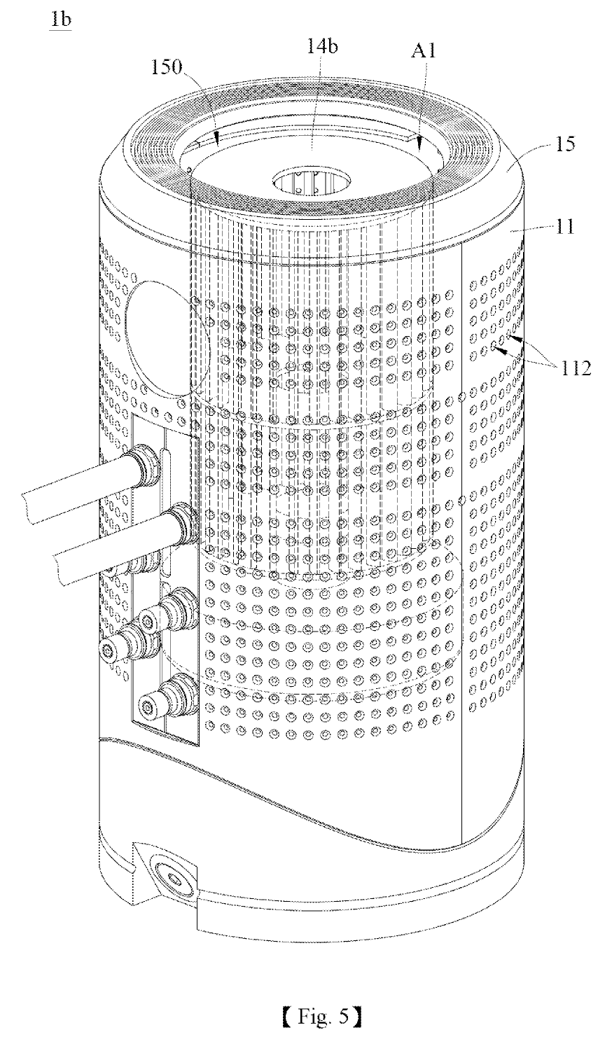

As an example, FIG. 5 is referred to, which is a three-dimensional schematic drawing of a coolant distribution unit according to a second example embodiment of the present disclosure. The coolant distribution unit 1b in the second example embodiment (corresponding to FIG. 5) can be similar to the coolant distribution unit 1 in the first example embodiment described above (corresponding to FIG. 1), and identical or similar labels are used to indicate identical or similar elements; the function and effect of each element that are the same as above, are not described again here for conciseness and not as a limitation.

The coolant distribution unit 1b in the second example embodiment and the coolant distribution unit 1 in the first example embodiment differ in the type of the on-axis cooling fan. In an exemplary implementation, in the second example embodiment, the on-axis cooling fan 14b can be a cross-flow fan, configured to generate a cooling gas flow that flows transversely, drawing in external air from the air guiding hole 150 of the air guiding cover 15, and by the principle of positive-pressure exhaust, discharging the air in the gas flow channel A1 from the openwork structure 112 of the casing 11 via the gaps between the metal heat exchange tubes and cooling fins of the cooling liquid radiator, thereby for example and without limitation enhancing the overall heat exchange effect. When the gas flow passes through the gaps between the metal heat exchange tubes and the cooling fins, it can for example and without limitation also, for example at the same time, carry away the heat distributed over the metal heat exchange tubes and the cooling fins, thereby for example and without limitation increasing the cooling efficiency.

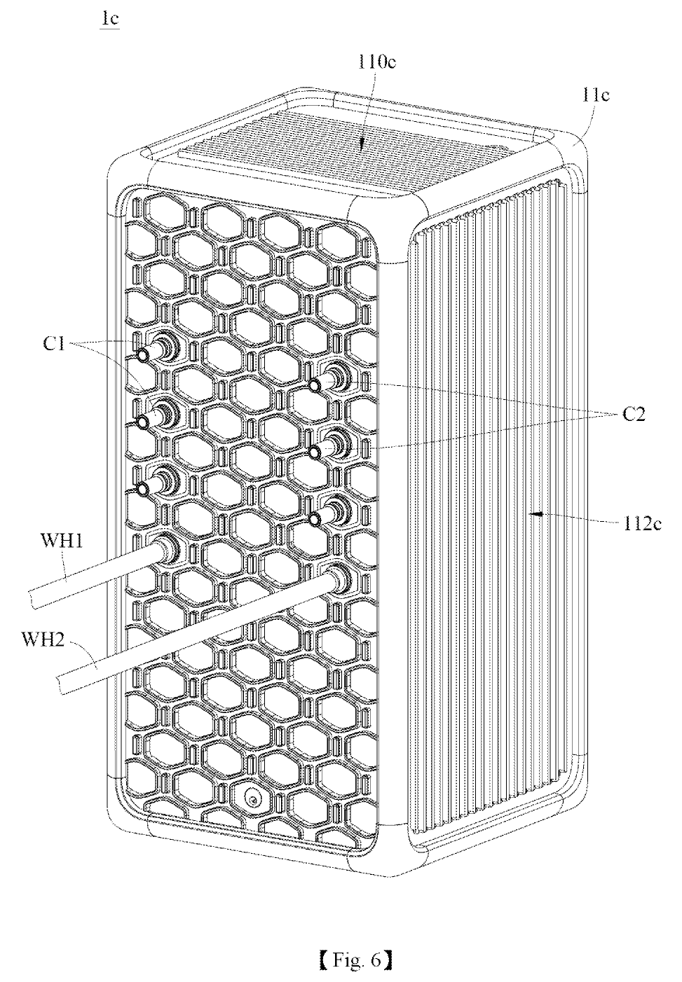

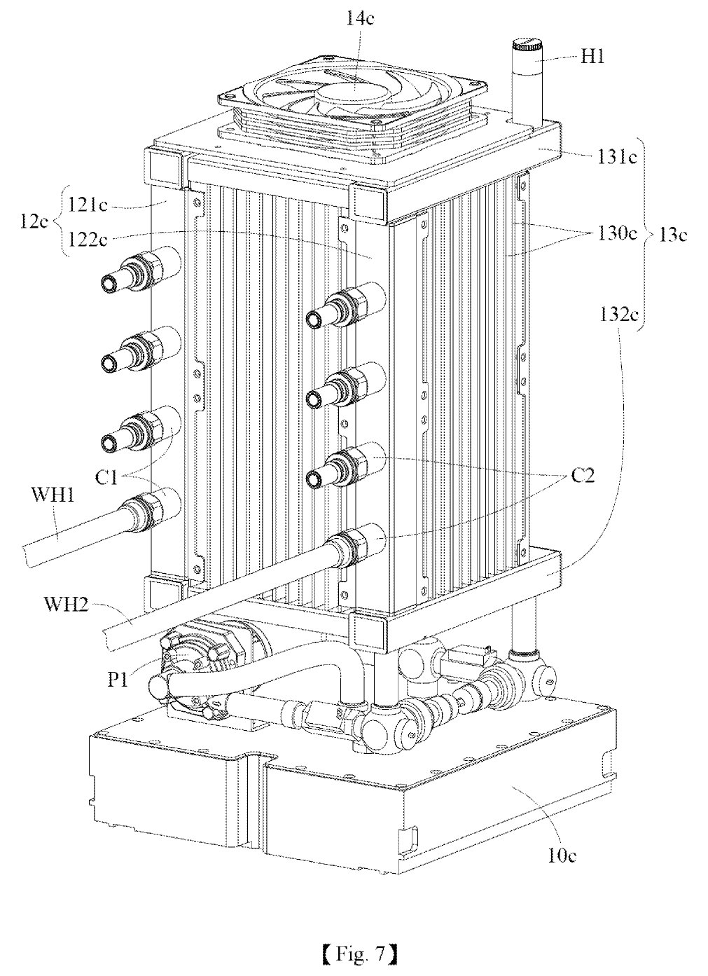

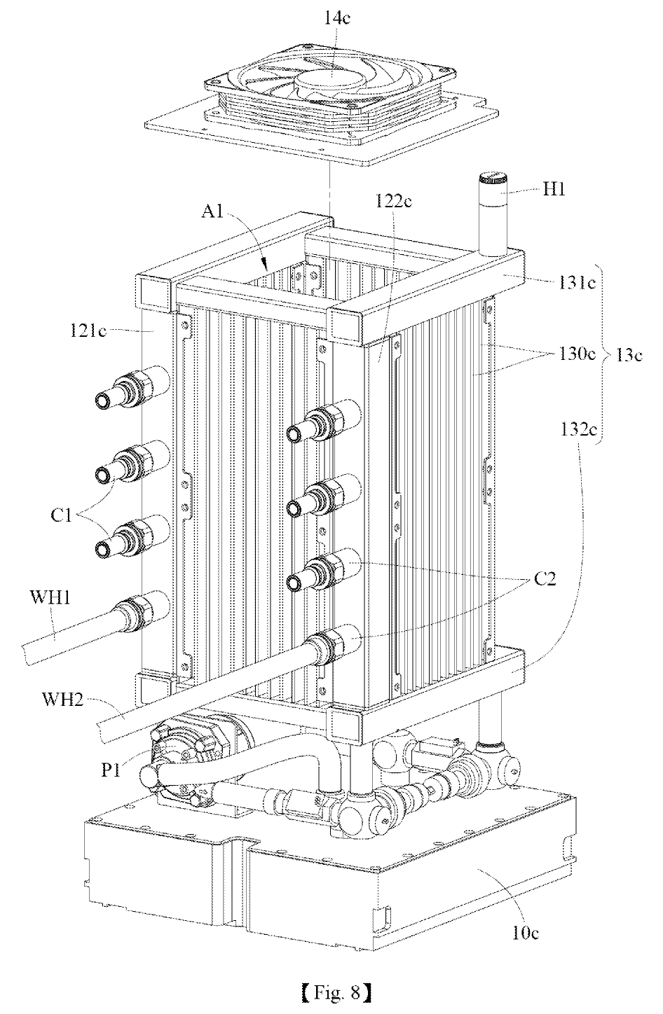

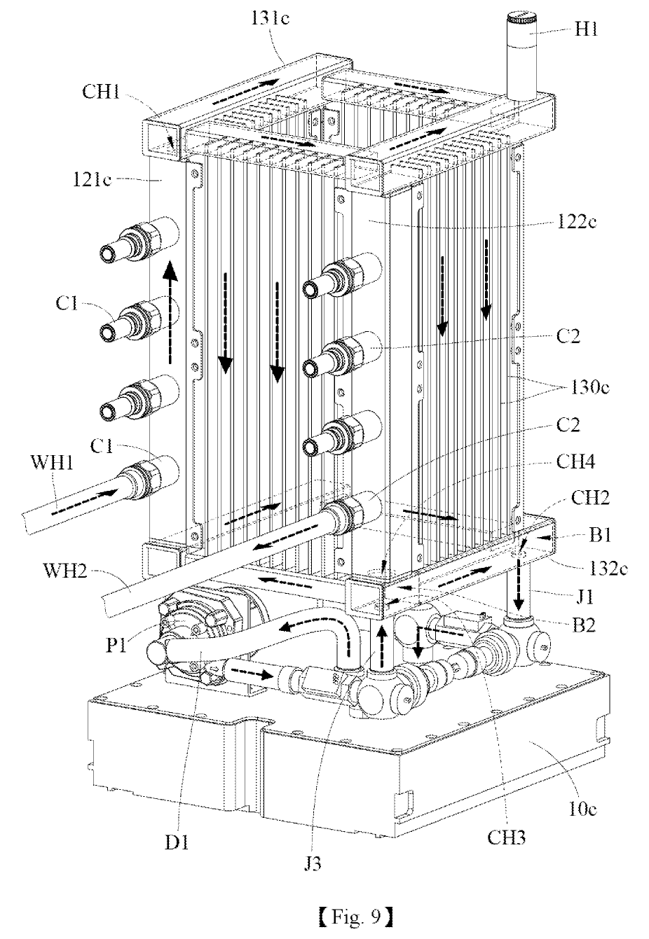

In the first example embodiment and the second example embodiment, the columnar structure can be cylindrical, but the present disclosure is not limited to the shape of the columnar structure described above. Referring to FIGS. 6-9, example embodiments are shown, where: FIG. 6 is an illustrative three-dimensional schematic drawing of a coolant distribution unit according to a third example embodiment of the present disclosure, FIG. 7 is an illustrative three-dimensional schematic drawing of the coolant distribution unit in FIG. 6 with the casing omitted, FIG. 8 is an exploded schematic drawing of the coolant distribution unit in FIG. 6 with the casing omitted, and FIG. 9 is a schematic drawing of the flow direction of working fluid in the coolant distribution unit in FIG. 6.

The coolant distribution unit 1c according to an implementation of a third example embodiment may comprise a base 10c, a casing 11c, a manifold assembly 12c, a cooling liquid radiator 13c, a pump P1, an on-axis cooling fan 14c, a water replenishment hole H1, a water drain valve (not labeled), a control circuit board (not shown), a power supply connector switch module (not shown) and a display screen module (not shown).

In an example implementation, the casing 11c can have an accommodating trough, and the casing 11c can have a ventilation port structure 110c, an opening structure (not separately labeled) and an openwork structure 112c. The base 10c can be arranged in the accommodating trough.

In an example implementation, the manifold assembly 12c can be configured to split the flow, or converge the flows, of a working fluid. The manifold assembly 12c can comprise a flow-converging manifold 121c and a flow-splitting manifold 122c, wherein the flow-converging manifold 121c can have multiple quick-release inflow connectors C1 and can be configured to converge the flows of working fluid, and the flow-splitting manifold 122c can have multiple quick-release outflow connectors C2 and can be configured to split the flow of working fluid. In this example embodiment, the flow-converging manifold 121c and the flow-splitting manifold 122c can be separated from each other, but the present disclosure is not limited to this.

In an example implementation, the cooling liquid radiator 13c can be in fluid communication with the manifold assembly 12c, and the cooling liquid radiator 13c can be configured to allow working fluid to circulate. The cooling liquid radiator 13c and the manifold assembly 12c together can form a columnar structure and can be arranged in the accommodating trough, and the columnar structure surrounds a gas flow channel A1. In this example embodiment, the columnar structure can be in the form of a square column.

In an example implementation, the ventilation port structure 110c of the casing 11c can correspond to the gas flow channel A1, to facilitate the entry and exit of gas flow. The opening structure of the casing 11c can correspond to and expose part of the manifold assembly 12c. The openwork structure 112c of the casing 11c can surround the cooling liquid radiator 13c and form channels allowing air to circulate between inner and outer spaces, such that for example and without limitation air can circulate between the gas flow channel A1 and the outer space via the openwork structure 112c.

In an example implementation, the pump P1 can be arranged in the accommodating trough and in fluid communication with the cooling liquid radiator 13c and the manifold assembly 12c, and the pump P1 can be configured to pump working fluid in the cooling liquid radiator 13c to the manifold assembly 12c. In this example embodiment, the manifold assembly 12c and the cooling liquid radiator 13c can be integrated and welded together, but the present disclosure is not limited to this.

In yet further example embodiment, the cooling liquid radiator 13c may comprise multiple metal heat exchange tubes 130c, a liquid exit water collection pipe 131c and a liquid entry water collection pipe 132c. The metal heat exchange tubes 130c can be arranged around the gas flow channel A1. The liquid exit water collection pipe 131c and the liquid entry water collection pipe 132c can be respectively located at two opposite ends of the metal heat exchange tubes 130c, and the liquid exit water collection pipe 131c and the liquid entry water collection pipe 132c can be in fluid communication with the metal heat exchange tubes 130c. The metal heat exchange tubes 130c may for example be flat tubes, but the present disclosure is not limited to this.

In an example implementation, the manifold assembly 12c may be fixed to the liquid exit water collection pipe 131c and the liquid entry water collection pipe 132c and located between the liquid exit water collection pipe 131c and the liquid entry water collection pipe 132c. The flow-converging manifold 121c and the flow-splitting manifold 122c of the manifold assembly 12c can be respectively located at two sides of one of the surfaces of the columnar structure. According to yet further example implementation, the flow-converging manifold 121c of the manifold assembly 12c may be welded to the liquid exit water collection pipe 131c and in fluid communication with the liquid exit water collection pipe 131c via a first connecting hole CH1, and the liquid exit water collection pipe 131c can be configured to split the flow of working fluid from the flow-converging manifold 121c into the metal heat exchange tubes 130c. The liquid entry water collection pipe 132c can be in fluid communication with the pump P1 and can be configured to converge the flows of working fluid from the metal heat exchange tubes 130c and guide same to the pump P1, and the pump P1 can be configured to pump working fluid from the liquid entry water collection pipe 132c to the flow-splitting manifold 122c of the manifold assembly 12c. In still further example implementation, the liquid entry water collection pipe 132c can have a liquid entry water collection chamber B1 and a linking chamber B2 which are separated from each other. The liquid entry water collection chamber B1 can be in fluid communication with the metal heat exchange tubes 130c via multiple collecting holes (not shown), and the liquid entry water collection chamber B1 can be in fluid communication with the pump P1 via a second connecting hole CH2, a first flow pipe member J1, an internal chamber (not shown) of the base 10c and a first pipe D1. The linking chamber B2 can be in fluid communication with the pump P1 via a third connecting hole CH3 and a second flow pipe member J2, and in fluid communication with the flow-splitting manifold 122c of the manifold assembly 12c via a fourth connecting hole CH4. The flow-splitting manifold 122c of the manifold assembly 12c may be welded to the liquid entry water collection pipe 132c. Through the above example configuration, the pump P1 can be configured to pump working fluid from the liquid entry water collection chamber B1 to the flow-splitting manifold 122c of the manifold assembly 12c via the linking chamber B2.

In an example implementation, the on-axis cooling fan 14c can be arranged at one end of the gas flow channel A1, and the on-axis cooling fan 14c can be configured to generate a cooling gas flow to cool the cooling liquid radiator 13c.

In an example implementation, the water replenishment hole H1 may be located on the liquid exit water collection pipe 131c, for example and without limitation to facilitate the replenishment of working fluid. The water drain valve may be connected to the liquid entry water collection pipe 132c, and configured to selectively discharge working fluid. This can for example and without limitation further increase convenience of maintenance and safety in use. However, the present disclosure is not limited to the positions of arrangement of the water replenishment hole and the water drain valve mentioned above. It should be understood that, according to example implementation, the water replenishment hole and the water drain valve may be arranged at different element positions in the fluid circuit according to actual design requirements.

In an example implementation, the power supply connector switch module and the display screen module can be electrically connected to the control circuit board. The control circuit board may be arranged in the accommodating trough, the power supply connector switch module may be arranged on the base 10c, and the display screen module may be arranged on the casing 11c. The opening structure of the casing 11c may expose at least part of the display screen module, such that the display screen module can be at least partially exposed through the opening structure of the casing 11c, for example and without limitation to provide the user with a monitoring and operating interface. In yet further example implementation, the power supply connector switch module can be an interface providing the coolant distribution unit 1c with power input and switch control.

As shown in FIG. 9, according to an example implementation, external working fluid to be cooled can be inputted through a hot liquid pipe member WH1 via the quick-release inflow connector C1 on the flow-converging manifold 121c, and can enter the liquid exit water collection pipe 131c through the first connecting hole CH1. The liquid exit water collection pipe 131c can then for example split the flow of the working fluid to be cooled and guide same into the metal heat exchange tubes 130c. When the working fluid to be cooled is flowing through the metal heat exchange tubes 130c, according to an example implementation the gas flow generated by the on-axis cooling fan 14c flows through the gas flow channel A1, carrying away the heat of the metal heat exchange tubes 130c and the working fluid therein, to achieve a cooling effect. The cooled working fluid converges in the liquid entry water collection chamber B1 of the liquid entry water collection pipe 132c through the collecting holes from the other ends of the metal heat exchange tubes 130c, and can be then delivered to the pump P1 through the second connecting hole CH2, the first flow pipe member J1, the internal chamber of the base 10c and the first pipe D1. The pump P1 can then pump the cooled working fluid to the linking chamber B2 of the liquid entry water collection pipe 132c via the second flow pipe member J2 and the third connecting hole CH3, and further guide same into the flow-splitting manifold 122c via the fourth connecting hole CH4, and finally output same to external equipment (such as a cold plate) (not shown) through a cold liquid pipe member WH2 via the quick-release outflow connector C2 on the flow-splitting manifold 122c.

According to an example implementation, through the above configuration, the cooling liquid radiator 13c and the manifold assembly 12c can be integrated as a columnar structure, such that for example and without limitation the cooling liquid radiator 13c can be distributed over the entire peripheral surface of the coolant distribution unit 1c; in this way, for example, the cooling area can be increased to increase the space utilization rate. In a further example implementation, the cooling liquid radiator 13c and the manifold assembly 12c can be welded together; for example and without limitation this can help to reduce the cost of pipe material used to connect the cooling liquid radiator 13c and the manifold assembly 12c in series, and also the piping production process, and for example and without limitation can further increase the space utilization rate and reduce the probability of water leakage. According to still further example implementation, having the on-axis cooling fan 14c arranged at one end of the gas flow channel A1, such that the on-axis cooling fan 14c can be located on a central axis of the gas flow channel A1, can facilitate more uniform circulation and distribution of the gas flow field over the cooling liquid radiator 13c.

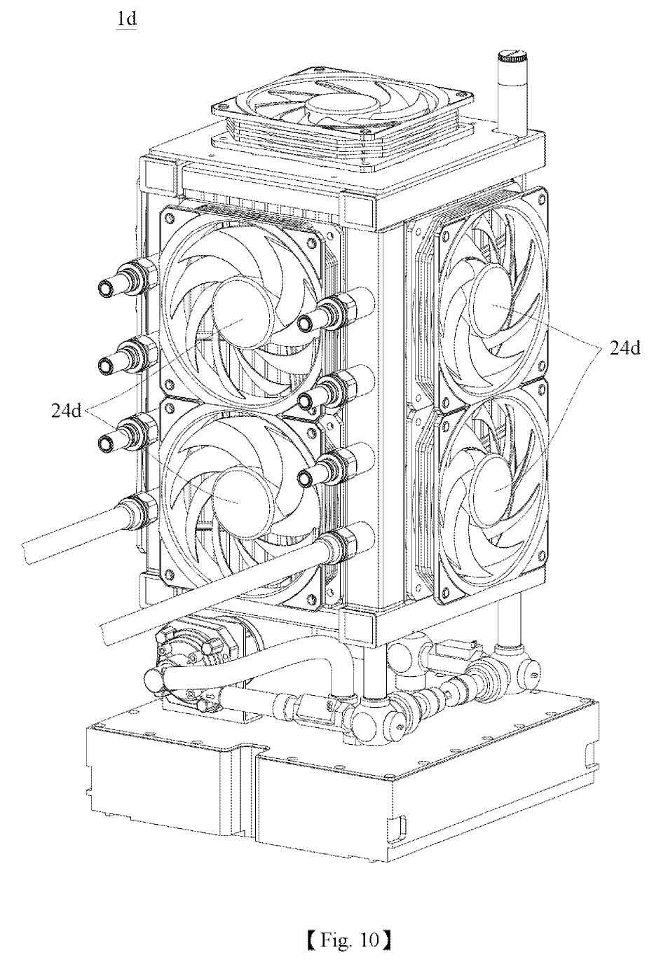

In this example embodiment, there is a single fan, but the present disclosure is not limited to this. FIG. 10 shows an illustrative three-dimensional schematic drawing of a coolant distribution unit according to a fourth example embodiment of the present disclosure. The coolant distribution unit 1d according to the fourth example embodiment (as illustrated in example of FIG. 10) is similar to the coolant distribution unit 1c according to the third example embodiment described above (as illustrated in example of FIGS. 6 and 7), and identical or similar labels are used to indicate identical or similar elements; the function and effect of each element that are the same as above, are not described again here for conciseness and not as a limitation.

The coolant distribution unit 1d in the fourth example embodiment and the coolant distribution unit 1c in the third example embodiment differ in the number of fans. According to an example implementation, in the fourth example embodiment, the coolant distribution unit 1d further comprises multiple external cooling fans 24d, and the external cooling fans 24d may be arranged on an outer surface of the cooling liquid radiator. In yet further example implementation, there may be eight of the external cooling fans 24d for example, and the eight external cooling fans 24d may be arranged on four outer surfaces of the columnar structure in the form of a square column, but the present disclosure is not limited with regard to the number of external cooling fans.

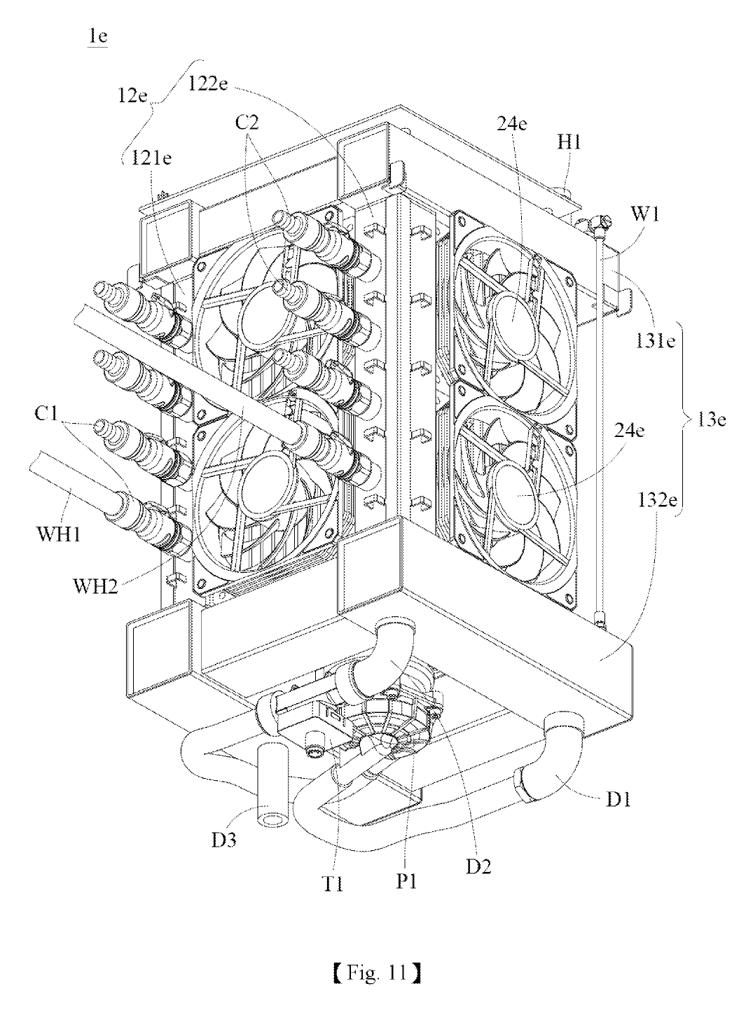

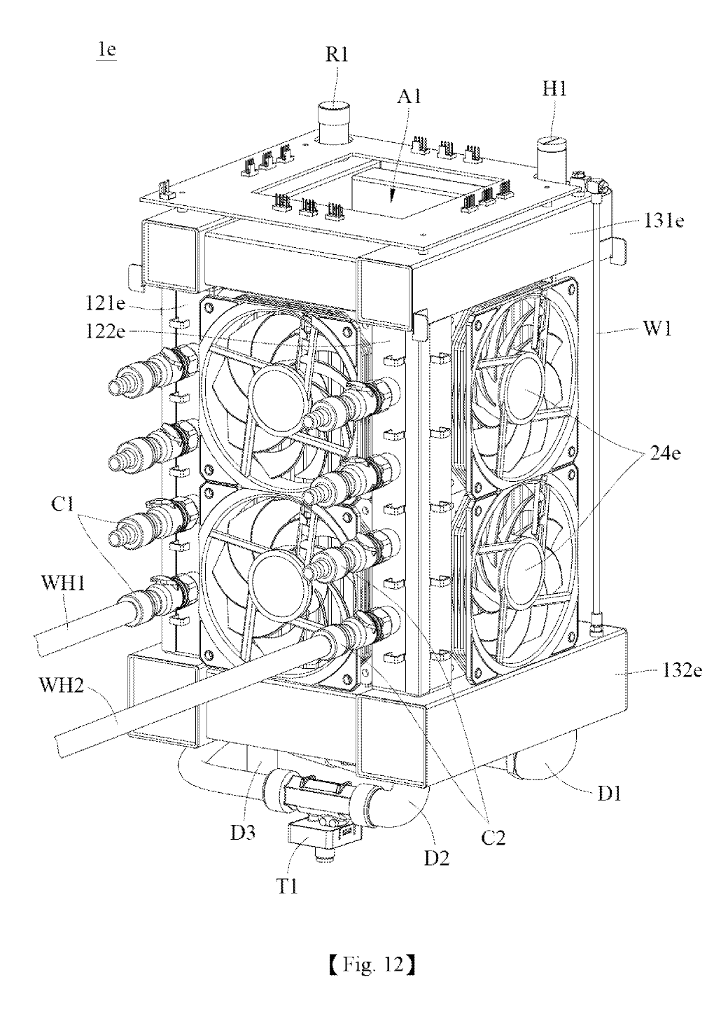

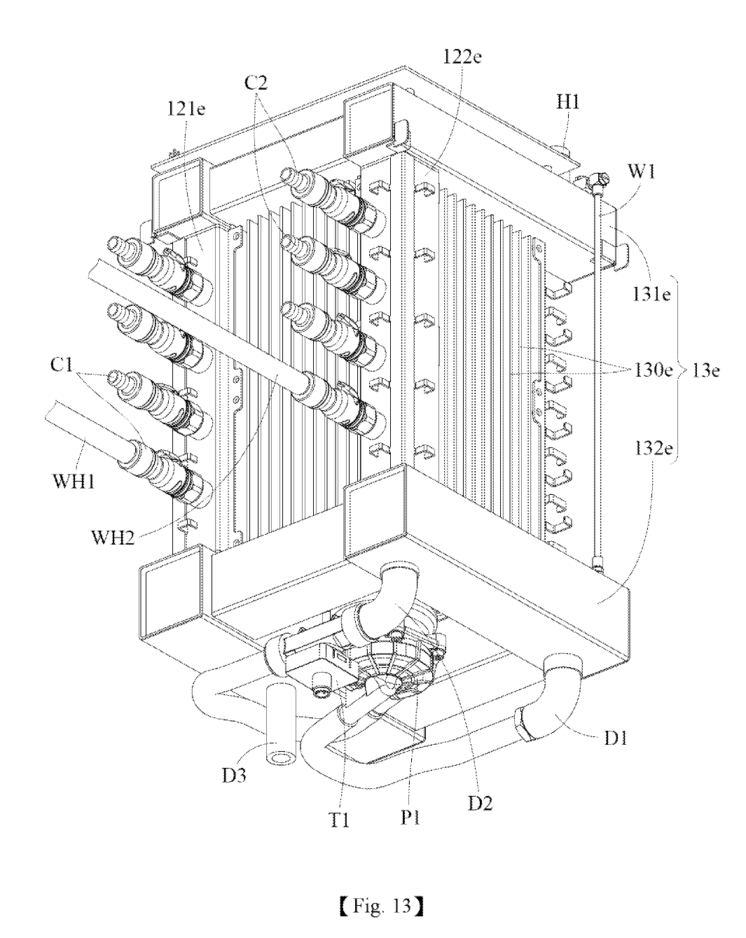

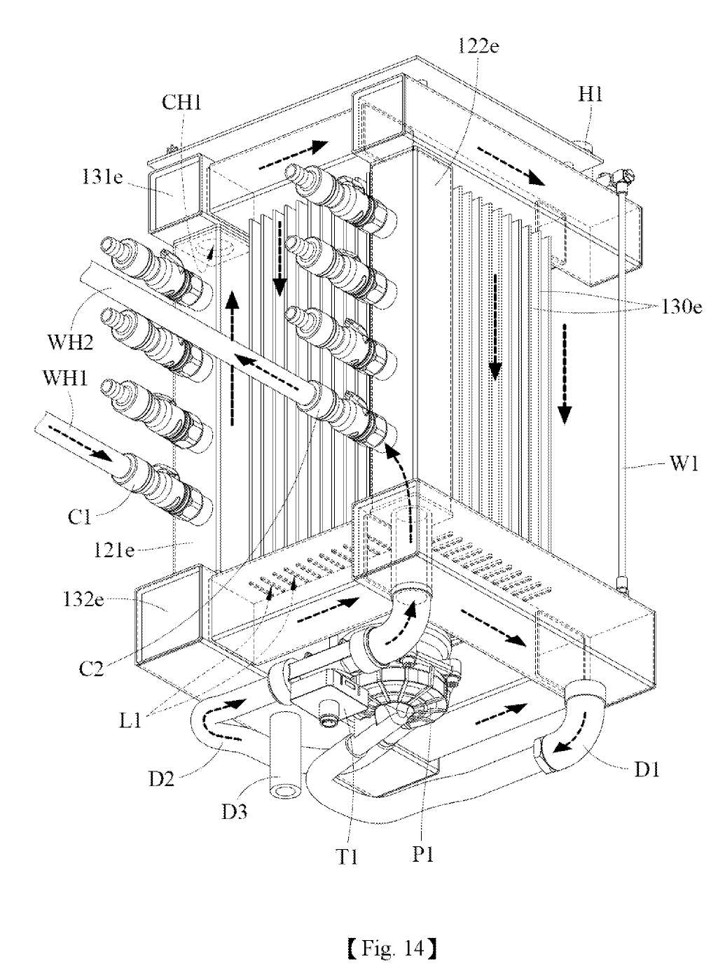

In the example embodiments above, all of the coolant distribution units can be provided with an on-axis cooling fan arranged in the gas flow channel or at one end of the gas flow channel, but the present disclosure is not limited to this. In other example embodiments, the coolant distribution unit may only be provided with external cooling fans on the outer surface of the cooling liquid radiator, and have no on-axis cooling fan. As an example, referring to FIGS. 11-14, where: FIG. 11 is an illustrative three-dimensional schematic drawing of a coolant distribution unit according to a fifth example embodiment of the present disclosure with the casing omitted, FIG. 12 is another three-dimensional schematic drawing of the coolant distribution unit in FIG. 11, FIG. 13 is a three-dimensional schematic drawing of the coolant distribution unit in FIG. 11 with the external cooling fans omitted, and FIG. 14 is a schematic drawing of the flow direction of working fluid in the coolant distribution unit in FIG. 13.

The coolant distribution unit 1e in this example embodiment may comprise a base (not shown), a casing (not shown), a manifold assembly 12e, a cooling liquid radiator 13e, a pump P1, a water replenishment hole H1, a water drain valve (not shown), a control circuit board (not shown), a power supply connector switch module (not shown), a display screen module (not shown), multiple external cooling fans 24e, an exhaust valve R1, a water level display member W1 and a sensor T1.

In an example implementation, the casing may be fixed to the base, and the casing and the base may together form an accommodating trough. The casing may have a ventilation port structure, an opening structure and an openwork structure (not shown).

In an example implementation, the manifold assembly 12e can be configured to split the flow, or converge the flows, of a working fluid. The manifold assembly 12e can comprise a flow-converging manifold 121e and a flow-splitting manifold 122e, wherein the flow-converging manifold 121e can have multiple quick-release inflow connectors C1 and can be configured to converge the flows of working fluid, and the flow-splitting manifold 122e can have multiple quick-release outflow connectors C2 and can be configured to split the flow of working fluid. In this example embodiment, the flow-converging manifold 121e and the flow-splitting manifold 122e can be separated from each other, but the present disclosure is not limited to this.

In an example implementation, the cooling liquid radiator 13e can be in fluid communication with the manifold assembly 12e, and the cooling liquid radiator 13e can be configured to allow working fluid to circulate. The cooling liquid radiator 13e and the manifold assembly 12e together can form a columnar structure and can be arranged in the accommodating trough jointly formed by the casing and the base, and the columnar structure can surround a gas flow channel A1. In this example embodiment, the columnar structure can be in the form of a square column.

In an example implementation, the ventilation port structure of the casing may correspond to and expose the gas flow channel A1, for example and without limitation to facilitate the entry and exit of gas flow. The opening structure of the casing may correspond to and expose the manifold assembly 12e. The openwork structure of the casing may surround the cooling liquid radiator 13e and form channels allowing air to circulate between inner and outer spaces, i.e. air can circulate between the gas flow channel A1 and the outer space via the openwork structure.

In an example implementation, the pump P1 can be arranged in the accommodating trough and in fluid communication with the cooling liquid radiator 13e and the manifold assembly 12e, and the pump P1 can be configured to pump working fluid in the cooling liquid radiator 13e to the manifold assembly 12e. In this example embodiment, the manifold assembly 12e and the cooling liquid radiator 13e can be integrated and welded together, but the present disclosure is not limited to this.

According to an example implementation, the cooling liquid radiator 13e may comprise multiple metal heat exchange tubes 130e, a liquid exit water collection pipe 131e and a liquid entry water collection pipe 132e. The metal heat exchange tubes 130e can be arranged around the gas flow channel A1. The liquid exit water collection pipe 131e and the liquid entry water collection pipe 132e can be respectively located at two opposite ends of the metal heat exchange tubes 130e, and the liquid exit water collection pipe 131e and the liquid entry water collection pipe 132e can be in fluid communication with the metal heat exchange tubes 130e. The metal heat exchange tubes 130e may for example be flat tubes, but the present disclosure is not limited to this.

In an example implementation, the manifold assembly 12e may be fixed to the liquid exit water collection pipe 131e and the liquid entry water collection pipe 132e and located between the liquid exit water collection pipe 131e and the liquid entry water collection pipe 132e. The flow-converging manifold 121e and the flow-splitting manifold 122e of the manifold assembly 12e can be respectively located at two sides of one of the surfaces of the columnar structure. In yet further example implementation, the flow-converging manifold 121e of the manifold assembly 12e may be welded to the liquid exit water collection pipe 131e and in fluid communication with the liquid exit water collection pipe 131e via a first connecting hole CH1, and the liquid exit water collection pipe 131e can be configured to split the flow of working fluid from the flow-converging manifold 121e into the metal heat exchange tubes 130e. The liquid entry water collection pipe 132e can be in fluid communication with the pump P1 and configured to converge the flows of working fluid from the metal heat exchange tubes 130e and guide same to the pump P1, and the pump P1 can be configured to pump working fluid from the liquid entry water collection pipe 132e to the flow-splitting manifold 122e of the manifold assembly 12e. In still further example implementation, the liquid entry water collection pipe 132e can be in fluid communication with the metal heat exchange tubes 130e via multiple collecting holes L1, and the liquid entry water collection pipe 132e can be in fluid communication with the pump P1 via a second connecting hole (not labeled) and a first pipe D1. The flow-splitting manifold 122e of the manifold assembly 12e can be in fluid communication with the pump P1 via a second pipe D2, wherein the second pipe D2 passes through the liquid entry water collection pipe 132e and thus directly connects the flow-splitting manifold 122e to the pump P1. The flow-splitting manifold 122e of the manifold assembly 12e may be welded to the liquid entry water collection pipe 132e. According to example implementation, through the above example configuration, the pump P1 can be configured to pump working fluid from the liquid entry water collection pipe 132e to the flow-splitting manifold 122e of the manifold assembly 12e via the first pipe D1 and the second pipe D2.

Compared with the liquid entry water collection pipe 132c in the third example embodiment, the liquid entry water collection pipe 132e in this example embodiment can have a sufficiently large accommodating space to accommodate working fluid, so that for example and without limitation there is no need to additionally provide an internal chamber for accommodating working fluid in the base. For example and without limitation, in this way, pipeline connections for connecting the liquid entry water collection pipe and the pump to the base can be reduced, and the overall height of the coolant distribution unit 1e can be reduced.

In an example implementation, the water replenishment hole H1 can be located on the liquid exit water collection pipe 131e, for example and without limitation to facilitate the replenishment of working fluid. The water drain valve can be connected to the liquid entry water collection pipe 132e via a third pipe D3, and configured to selectively discharge working fluid. For example and without limitation, this can further increase convenience of maintenance and safety in use. However, the present disclosure is not limited to the positions of arrangement of the water replenishment hole H1 and the water drain valve mentioned above. It should be understood that, according to example implementations, the water replenishment hole and the water drain valve may be arranged at different element positions in the fluid circuit according to actual design requirements.

In an example implementation, the power supply connector switch module and the display screen module can be electrically connected to the control circuit board. The control circuit board may be arranged in the accommodating trough, the power supply connector switch module may be arranged on the base, and the display screen module may be arranged on the casing. The opening structure of the casing may expose at least part of the display screen module, such that the display screen module can be at least partially exposed through the opening structure of the casing, for example and without limitation to provide the user with a monitoring and operating interface. In yet further example implementations, the power supply connector switch module can be an interface providing the coolant distribution unit 1e with power input and switch control.

In an example implementation, the external cooling fans 24e may be arranged on outer surfaces of the cooling liquid radiator 13e. In yet further example implementation, there may be eight of the external cooling fans 24e, and the eight external cooling fans 24e may be arranged on four outer surfaces of the columnar structure in the form of a square column, and can be configured to generate a cooling gas flow to cool the cooling liquid radiator 13e, but the present disclosure is not limited with regard to the number of external cooling fans.

In an example implementation, the exhaust valve R1 may be arranged on the liquid exit water collection pipe 131e, and can be configured to discharge gas in the system (especially residual air or bubbles), for example and without limitation preventing the phenomenon of gas resistance from occurring, to ensure stable operation of the entire liquid cooling circuit, and cooling efficiency. The exhaust valve R1 may for example be an automatic exhaust valve or a manual rotary-knob exhaust valve, but the present disclosure is not limited to this.

In an example implementation, the water level display member W1 can be arranged in the cooling liquid radiator 13e, and configured to display the liquid level state of working fluid in the cooling liquid radiator 13e; by observing the liquid surface height displayed by the water level display member W1, the user can judge whether there is sufficient working fluid in the system, so as to perform a liquid replenishment task at the appropriate time. The water level display member W1 may be an observation tube with a transparent viewing window or a liquid level scale, or may be an electronic liquid level sensing module, and may selectively be electrically connected to the display screen module, to promptly display liquid level information, or realize a low liquid level alert function in conjunction with the control circuit board. The water level display member W1 for example and without limitation can enable the user to effectively ascertain the consumption of coolant, avoiding pump idling or reduced cooling performance due to an excessively low liquid level, and further improving the stability and safety of the unit in use. When the user pours working fluid in through the water replenishment hole H1, the user can observe the change in liquid level via the water level display member W1, and open the exhaust valve R1 in a coordinated manner to discharge gas, so as to ensure that the entire cooling circuit achieves a state in which it is completely filled with liquid.

In an example implementation, the sensor T1 can be arranged on the second pipe D2, and may be configured to sense the flow speed and/or temperature of cooled working fluid flowing through the second pipe D2, and transmit the sensed data to the control circuit board, to allow the control system to perform operating state monitoring, data analysis, or regulating control of the fans and the pump, for example and without limitation so as to improve the operating efficiency and stability of the system. The display screen module may display flow speed and/or temperature values of the cooled working fluid detected by the sensor T1, and the user can promptly monitor the operating state of working fluid inside the system via the display screen module, so as to ascertain the cooling performance and the pump operating status; this may also serve as the basis for fault determination or maintenance inspection.

According to an example implementation, as shown in FIG. 14, external working fluid to be cooled can be inputted through a hot liquid pipe member WH1 via the quick-release inflow connector C1 on the flow-converging manifold 121e, and enter the liquid exit water collection pipe 131e through the first connecting hole CH1. The liquid exit water collection pipe 131e can be configured to then split the flow of the working fluid to be cooled and guide same into the metal heat exchange tubes 130e. When the working fluid to be cooled is flowing through the metal heat exchange tubes 130e, the gas flow generated by the external cooling fans 24e carries away the heat of the metal heat exchange tubes 130e and the working fluid therein, to achieve a cooling effect. The cooled working fluid converges in the liquid entry water collection pipe 132e through the collecting holes L1 from the other ends of the metal heat exchange tubes 130e, and is then delivered to the pump P1 through the second connecting hole and the first pipe D1. The pump P1 then pumps the cooled working fluid to the flow-splitting manifold 122e via the second pipe D2, and finally outputs same to external equipment (such as a cold plate) (not shown) through a cold liquid pipe member WH2 via the quick-release outflow connector C2 on the flow-splitting manifold 122e.

According to an example implementation, through the above configuration, the cooling liquid radiator 13e and the manifold assembly 12e can be integrated as a columnar structure, such that the cooling liquid radiator 13e can be distributed over the entire peripheral surface of the coolant distribution unit 1e. In this way, in example implementation, the cooling area can be increased to increase the space utilization rate. In yet further example implementation, the cooling liquid radiator 13e and the manifold assembly 12e can be welded together. For example and without limitation, this can help to reduce the cost of pipe material used to connect the cooling liquid radiator 13e and the manifold assembly 12e in series, and also the piping production process, and can further increase the space utilization rate and reduce the probability of water leakage.

In the coolant distribution unit according to the example embodiment above, the cooling liquid radiator and the manifold assembly can be integrated as a columnar structure, such that the cooling liquid radiator can be distributed over the entire peripheral surface of the coolant distribution unit. In this way, in example implementation, the cooling area can be increased to increase the space utilization rate. In yet further example implementation, the cooling liquid radiator and the manifold assembly are welded together. For example and without limitation, this can help to reduce the cost of pipe material used to connect the cooling liquid radiator and the manifold assembly in series, and also the piping production process, and can further increase the space utilization rate and reduce the probability of water leakage.

In an example embodiment, having the on-axis cooling fan arranged in the gas flow channel or at one end of the gas flow channel, such that the on-axis cooling fan is located on the central axis of the gas flow channel, can facilitate more uniform circulation and distribution of the gas flow field over the cooling liquid radiator.

The above-presented description and figures are intended by way of example only and are not intended to limit the disclosed illustrative example embodiments in any way except as set forth in the appended claims and full equivalents thereof. It is particularly noted that various technical aspects of the various elements of the various exemplary embodiments that have been described above can be combined in numerous other ways, all of which are considered to be within the scope of the disclosure.

Accordingly, although exemplary implementations of example embodiments have been disclosed, these are not intended to limit the present disclosure, and any person skilled in the art should be able to make changes and modifications without departing from the spirit and scope of the present disclosure. Therefore, the scope of patent protection of the present disclosure shall be as defined by the claims attached hereto and equivalents thereof.

The terms and corresponding labels referenced in the disclosure are listed below for convenience. As would be readily appreciated by skilled artisans in the relevant art, while these and other descriptive terms are used throughout this specification to facilitate understanding, it is not intended to limit any components that can be used in combinations or individually to implement various aspects of the embodiments of the present disclosure.
1, 1b, 1c, 1d, 1e: Coolant distribution device
10, 10c: Base
11, 11c: Casing
12, 12c, 12e: Manifold assembly
13, 13c, 13e: Cooling liquid radiator
14, 14b, 14c: On-axis cooling fan
15: Air guiding cover
16: Light strip
17: Control circuit board
18: Power supply connector switch module
19: Display screen module
110, 110c: Ventilation port structure
111: Opening structure
112, 112c: Openwork structure
121, 121c, 121e: Flow-converging manifold
122, 122c, 122e: Flow-splitting manifold
130, 130c, 130e: Metal heat exchange tube
131, 131c, 131e: Liquid exit water collection pipe
132, 132c, 132e: Liquid entry water collection pipe
150: Air guiding hole
24d, 24e: External cooling fan
A1: Gas flow channel
B1: Liquid entry water collection chamber
B2: Linking chamber
C1: Quick-release inflow connector
C2: Quick-release outflow connector
CH1: First connecting hole
CH2: Second connecting hole
CH3: Third connecting hole
CH4: Fourth connecting hole
D1: First pipe
D2: Second pipe
D3: Third pipe
F1: Cooling fin
H1: Water replenishment hole
J1: First flow pipe member
J2: Second flow pipe member
L1: Collecting hole
P1: Pump
R1: Exhaust valve
T1: Sensor
V1: Water drain valve
W1: Water level display member
WH1: Hot liquid pipe member
WH2: Cold liquid pipe member

1. A coolant distribution unit comprising:
a manifold assembly, configured to split a flow, or converge flows, of a working fluid;
a cooling liquid radiator, in fluid communication with the manifold assembly and configured to allow the working fluid to circulate, the cooling liquid radiator and the manifold assembly together forming a columnar structure and surrounding a gas flow channel; and
a pump, in fluid communication with the cooling liquid radiator and the manifold assembly, the pump configured to pump the working fluid in the cooling liquid radiator to the manifold assembly.

2. The coolant distribution unit as claimed in claim 1, wherein the columnar structure comprises a cylindrical shape.

3. The coolant distribution unit as claimed in claim 1, wherein the manifold assembly and the cooling liquid radiator are integrated.

4. The coolant distribution unit as claimed in claim 1, further comprising an on-axis cooling fan,
wherein the on-axis cooling fan is arranged in the gas flow channel, and the on-axis cooling fan is configured to generate a cooling gas flow to cool the cooling liquid radiator.

5. The coolant distribution unit as claimed in claim 4, wherein the on-axis cooling fan is an axial-flow fan or a cross-flow fan.

6. The coolant distribution unit as claimed in claim 1, wherein
the manifold assembly comprises a flow-converging manifold and a flow-splitting manifold,
the flow-converging manifold comprises multiple quick-release inflow connectors and is configured to converge flows of the working fluid, and
the flow-splitting manifold comprises multiple quick-release outflow connectors and is configured to split flow of the working fluid.

7. The coolant distribution unit as claimed in claim 6, wherein
the cooling liquid radiator comprises multiple metal heat exchange tubes, a liquid exit water collection pipe and a liquid entry water collection pipe,
the metal heat exchange tubes being arranged to surround the gas flow channel,
the liquid exit water collection pipe and the liquid entry water collection pipe are respectively located at two opposite ends of the metal heat exchange tubes and in fluid communication with the metal heat exchange tubes,
the flow-converging manifold is welded to the liquid exit water collection pipe and in fluid communication with the liquid exit water collection pipe via a first connecting hole,
the liquid exit water collection pipe is configured to split flow of the working fluid from the flow-converging manifold into the metal heat exchange tubes,
the liquid entry water collection pipe is in fluid communication with the pump,
the liquid entry water collection pipe is configured to converge flows of the working fluid from the metal heat exchange tubes and guide same to the pump, and
the pump is configured to pump the working fluid from the liquid entry water collection pipe to the flow-splitting manifold.

8. The coolant distribution unit as claimed in claim 7, wherein
the manifold assembly is fixed to the liquid exit water collection pipe and the liquid entry water collection pipe and located between the liquid exit water collection pipe and the liquid entry water collection pipe,
the manifold assembly is arranged between two of the metal heat exchange tubes,
the liquid entry water collection pipe has a liquid entry water collection chamber and a linking chamber which are separated from each other,
the liquid entry water collection chamber is in fluid communication with the metal heat exchange tubes via multiple collecting holes,
the liquid entry water collection chamber is in fluid communication with the pump via a second connecting hole and a first pipe,
the linking chamber is in fluid communication with the pump via a third connecting hole and a second pipe,
the linking chamber is in fluid communication with the flow-splitting manifold via a fourth connecting hole, and
the pump is configured to pump the working fluid from the liquid entry water collection chamber to the flow-splitting manifold via the linking chamber.

9. The coolant distribution unit as claimed in claim 7, wherein the cooling liquid radiator further comprises multiple cooling fins, the cooling fins being connected and arranged between two adjacent said metal heat exchange tubes.

10. The coolant distribution unit as claimed in claim 7, further comprising:
a water replenishment hole; and
a water drain valve,
wherein
the water replenishment hole is located on the liquid exit water collection pipe, and
the water drain valve is connected to the liquid entry water collection pipe.

11. The coolant distribution unit as claimed in claim 6, wherein the flow-converging manifold and the flow-splitting manifold are fixedly connected to each other.

12. The coolant distribution unit as claimed in claim 1, further comprising:
a base; and
a casing,
wherein
the casing is fixed to the base and, together therewith, forms an accommodating trough in which the columnar structure is arranged,
the casing has a ventilation port structure, an opening structure and an openwork structure,
the ventilation port structure corresponds to the gas flow channel,
the opening structure corresponds to and exposes at least part of the manifold assembly, and
the openwork structure surrounds the cooling liquid radiator, enabling air to circulate between the gas flow channel and an outer space via the openwork structure.

13. The coolant distribution unit as claimed in claim 12, further comprising:
an air guiding cover; and
a light strip,
wherein
the base and the air guiding cover are respectively located at two opposite ends of the columnar structure,
the air guiding cover is fitted to the casing and has an air guiding hole which exposes the gas flow channel, and
the light strip is arranged on the air guiding cover and surrounds the air guiding hole.

14. The coolant distribution unit as claimed in claim 13, further comprising:
a control circuit board;
a display screen module; and
a power supply connector switch module electrically connected to the control circuit board,
wherein
the control circuit board and the power supply connector switch module are arranged on the base,
the display screen module is arranged on the casing, and
the opening structure of the casing exposes at least part of the display screen module.

15. The coolant distribution unit as claimed in claim 1, further comprising multiple external cooling fans, wherein the external cooling fans are arranged on an outer surface of the cooling liquid radiator.

16. The coolant distribution unit as claimed in claim 1, wherein the columnar structure comprises a square column shape.

17. The coolant distribution unit as claimed in claim 3, wherein the manifold assembly and the cooling liquid radiator are welded together.

18. The coolant distribution unit as claimed in claim 1, further comprising an on-axis cooling fan, wherein the on-axis cooling fan is arranged at one end of the gas flow channel, and the on-axis cooling fan is configured to generate a cooling gas flow to cool the cooling liquid radiator.

19. The coolant distribution unit as claimed in claim 6, wherein the flow-converging manifold and the flow-splitting manifold are separated from each other.

20. The coolant distribution unit as claimed in claim 18, wherein the on-axis cooling fan is an axial-flow fan or a cross-flow fan.
